(19) United States
(12) Patent Application Publication
(10) Pub. No.: US 2018/0198027 A1
(43) Pub. Date: Jul. 12, 2018

(54) ELECTRON EMITTER AND LIGHT EMITTING APPARATUS COMPRISING SAME

(71) Applicant: Korea Advanced Institute of Science and Technology, Daejeon (KR)

(72) Inventors: Yong Hoon Cho, Daejeon (KR); Jong Hoi Cho, Daejeon (KR); Je Hyung Kim, Daejeon (KR)

(21) Appl. No.: 15/746,388

(22) PCT Filed: Jan. 21, 2016
(86) PCT No.: PCT/KR2016/000630

§ 371 Date: Jan. 19, 2018

(30) Foreign Application Priority Data
Jul. 23, 2015 (KR) 10-2015-0104400

(51) Int. Cl. H01L 33/32; B82Y 40/00; H01J 1/308; H01J 9/02; H01L 33/54; H01L 33/10

(52) U.S. Cl. CPC H01L 33/32; B82Y 40/00; H01L 33/10; H01J 9/025; H01L 33/54; H01J 1/308

(57) ABSTRACT

The present invention relates to an electron emitter, a method for manufacturing the same, and a light emitting apparatus comprising the same, and, more particularly, to an electron emitter comprising a semiconductor wafer having a nanostructure formed in at least a portion thereof. The present invention is capable of providing a large-area electron emitter, and also capable of providing a light emitting apparatus which has improved light emission efficiency and can be operated by an electron injection method.

### RELATED ART

At least one example embodiment relates to an electron emitter, a method of manufacturing the electron emitter, and a light emitting device including the electron emitter.

### RELATED ART

Although a mercury lamp, an excimer laser, etc., may be used as an ultraviolet (UV) light emitting source, an safety issue by using harmful materials and an efficiency issue have been raised. Also, the utilization is significantly low in that an UV light emitting wavelength band is fixed.

A UV light emitting diode (LED) is proposed as a device capable of adjusting the materialistic stability and the light emitting wavelength range. However, an existing commercialized UV LED may have the following issues. For example, a p-type AlGaN layer doped with Mg needs to be formed in an LED structure for electric operation. However, since the ionization energy of Mg is high and the carrier concentration of holes is low in a room temperature, a recombination rate between electrons and holes decreases, which leads to decreasing the light emission efficiency.

To ensure a sufficient hole carrier concentration, a p-type GaN layer may be used. However, UV emitted by activation of a semiconductor is mostly absorbed at the p-type GaN layer to cause a degradation in the light extraction efficiency. During sample growth and processing, a configuration, for example, an electron block layer, a reflective p-type contact, and a UV transparent p-type contact, needs to be employed. The application of such a configuration makes a manufacturing process complex and does not distinctly enhance the light emission efficiency.

### DETAILED DESCRIPTION

### Subjects

The present disclosure is conceived to outperform the issues found in the art and at least one example embodiment provides an electron emitter that may exhibit a high performance electron emission characteristic and may form a large-area nanostructure, and a method of manufacturing the electron emitter.

At least one example embodiment also provides a light emitting device including an electron emitter that may perform ultraviolet (UV) emission using an electron operation scheme and may have the enhanced light emission efficiency.

Subjects to be outperformed herein are not limited to the aforementioned subjects and other subjects not described herein may be clearly understood from the following description.

### Solutions

According to an aspect, there is provided an electron emitter including a semiconductor wafer including a nanostructure formed on at least a portion of the semiconductor wafer.

According to an example embodiment, the nanostructure may be formed using the same component as that of the semiconductor wafer and may be in a structure that continues from the semiconductor wafer.

According to an example embodiment, the nanostructure may be formed on the semiconductor wafer through chemical etching and the nanostructure and the semiconductor wafer may be in a continuous structure.

According to an example embodiment, the nanostructure may be in a shape of at least one of a needle, a cone, and a polygonal pyramid.

According to an example embodiment, the nanostructure may have an aspect ratio of 2 to 500.

According to an example embodiment, the nanostructure may be separate at an interval of 0.01 to 1 fold of a height of the nanostructure.

According to an example embodiment, the nanostructure may have a height of 10 nm to 50 nm.

According to an example embodiment, each of the semiconductor wafer and the nanostructure may include a group III nitride semiconductor including a group III element and nitrogen (N).

According to an example embodiment, the group III nitride semiconductor may include GaN.

According to another aspect, there is provided a method of manufacturing an electron emitter, the method including providing a semiconductor wafer; and forming a nanostructure on at least a portion of the semiconductor wafer.

According to an example embodiment, the forming of the nanostructure may include forming the nanostructure through chemical etching, and the chemical etching may be performed using HCl, NH₃, or both of HCl and NH₃.

According to another aspect, there is provided a light emitting device including a first substrate and a second substrate provided to face each other: an electron emitting portion including a semiconductor wafer layer provided on one surface of the first substrate and including a nanostructure formed on at least a portion of the semiconductor wafer layer; and a light emitter including a light emitting material layer provided on one surface of the second substrate and provided toward the nanostructure.

According to an example embodiment, the light emitting material layer may include a light emitting material that emits light by an electron emitted from the electron emitting portion, and the light emitting material layer may have a thickness of 1 nm to 20 μm.

According to an example embodiment, the electron emitting portion and the light emitter may be provided so that a gap is formed between the electron emitting portion and the light emitter, and a length of the gap may be adjustable.

According to an example embodiment, the first substrate and the second substrate may be formed suing the same component or different components, and each of the first substrate and the second substrate may include at least one of sapphire, diamond sapphire, diamond, LiAlO₂, Al, SiO₂, Si, SiC, GaN, Cu, Fe, Pt, and Pb, and may have a thickness of 10 μm to 500 μm.

According to an example embodiment, a reflective layer, an electron collecting layer, or both of the reflective layer and the electron collecting layer may be further sequentially provided toward the nanostructure on at least a portion of one surface of the light emitting material layer.

According to an example embodiment, each of the reflective layer and the electron collecting layer may include at least one of Ni, Al, Cu, Fe, Ag, Zn, Sn, Pb, Sb, Ti, In, V, Cr, Co, C, Ca, Mo, Au, P, W, Rh, Mn, B, Si, Ge, Se, Ln, Ga, Ir, and alloy thereof.

According to an example embodiment, each of the reflective layer and the electron collecting layer may have a thickness of 10 nm to 200 nm.

According to an example embodiment, a metal plate configured to connect to an external electrode may be provided on at least a portion of the first substrate and the light emitting material layer.

### Effect

According to example embodiments, there may be provided a high performance electron emitter that may operate a light emitting device using an electron emission injection scheme.

Also, according to example embodiments, it is possible to uniformly manufacture nanostructures on a large area on the whole surface of a semiconductor wafer.

Also, according to example embodiments, there may be provided a light emitting device that may operate through an electron emission injection scheme using an electron emitter and thus, may emit light with energy of emitted electrons without using a p-type (Al)GaN layer and may have the enhanced emission efficiency.

Also, according to example embodiments, it is possible to simply manufacture a light emitting device without using a complex growth process, such as an existing p-type (Al)GaN layer forming process.

### BRIEF DESCRIPTION OF THE DRAWINGS

FIG. 1A illustrates an example of an electron emitter according to an example embodiment.

FIGS. 1B and 1C illustrate examples of a semiconductor wafer according to an example embodiment.

FIGS. 1D through 1G illustrate examples of a shape and an arrangement of a nanostructure according to an example embodiment.

FIG. 2A is a flowchart illustrating an example of a method of manufacturing an electron emitter according to an example embodiment.

FIG. 2B illustrates an example of a process of manufacturing an electron emitter according to an example embodiment.

FIGS. 3A through 3C illustrate examples of a light emitting device according to an example embodiment.

FIGS. 3D through 3H illustrate examples of a light emitting material layer according to an example embodiment.

FIGS. 4A and 4B illustrate examples of a light emitting device to which a vacuum line is connected according to an example embodiment.

FIGS. 5A through 5C illustrate examples of an image of a manufactured electron emitter according to an example embodiment.

FIG. 6 is a graph showing a result of an electron emission characteristic measured according to Experiment 1 of an example embodiment.

FIG. 7 is a graph showing a result of an ultraviolet (UV) emission characteristic measured according to Experiment 2 of an example embodiment.

FIGS. 8A and 8B illustrate images of a UV light emitting device manufactured according to Manufacture example 1 of an example embodiment and an emission characteristic thereof.

### BEST MODE

Hereinafter, example embodiments will be described with reference to the accompanying drawings. Herein, when it is determined that detailed description related to a known function or configuration they may make the purpose of the example embodiments unnecessarily ambiguous in describing the example embodiments, the detailed description will be omitted. Also, terminologies used herein are defined to appropriately describe the example embodiments and thus, may be changed depending on a user, the intent of an operator, or a custom. Accordingly, the terminologies need to be defined based on the following overall description of this specification. Reference numerals proposed in each drawing refer to like elements throughout.

The example embodiments relate to an electron emitter that includes a semiconductor wafer in which at least one nanostructure is formed.

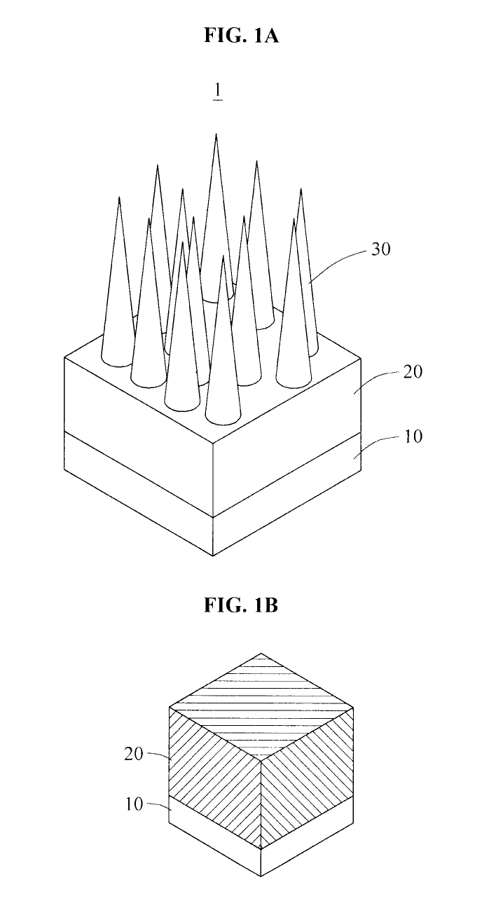

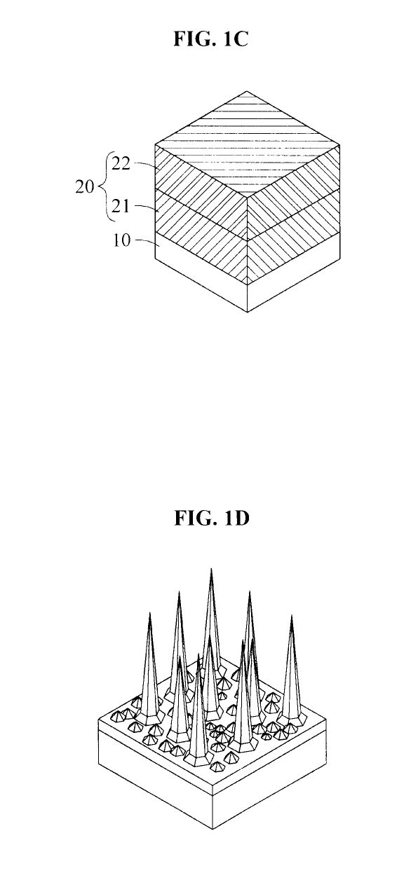

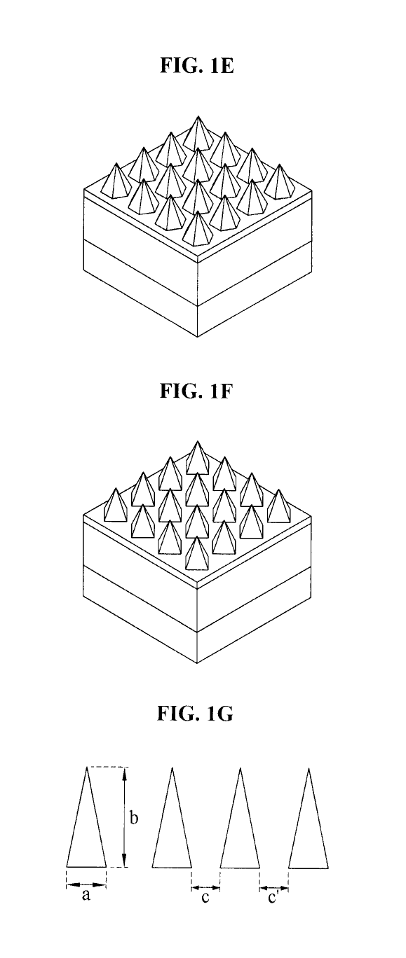

An electron emitter according to an example embodiment will be described with reference to FIGS. 1A through 1G. FIG. 1A illustrates an example of an electron emitter 1 according to an example embodiment. Referring to FIG. 1A, the electron emitter 1 may include a substrate 10 and a semiconductor wafer 20.

The substrate 10 may be an amorphous or crystalline substrate that includes at least one of inorganic, organic, and metal materials according to an example embodiment. For example, the substrate 10 may include at least one of sapphire, diamond, LiAlO₂, Al, SiO₂, Si, SiC, GaN, Cu, Fe. Pt, and Pb. The substrate 10 may have a thickness of 10 μm to 500 μm, desirably, a thickness of 50 μm to 200 μm.

The semiconductor wafer 20 may include at least one nanostructure 30 on at least a portion of one surface of the semiconductor wafer 20.

According to an example embodiment, the nanostructure 30 may be formed to have a small area of less than 1 inch or may be formed on a large area of 1 inch or more, desirably, 12 inches or more, on the semiconductor wafer 20.

According to an example embodiment, the semiconductor wafer 20 and the nanostructure 30 are in a continuous structure. For example, the nanostructure 3o that continues from the semiconductor wafer 20 may be formed by chemically etching the semiconductor wafer 20. An etching process is described below.

According to an example embodiment, the semiconductor wafer 20 and the nanostructure 30 may include the same semiconductor material or different semiconductor materials. For example, FIGS. 1B and 1C illustrate examples of the semiconductor wafer 20 according to an example embodiment. Referring to FIG. 1B, the semiconductor wafer 20 may be formed using a single type of a semiconductor material. The nanostructure 30 of the same component as that of the semiconductor wafer 20 may be formed by etching at least a portion of the semiconductor wafer 20. Alternatively, referring to FIG. 1C, different two semiconductor materials, for example, a u-type semiconductor material layer 21 and an n-type semiconductor material 22 may be sequentially formed. The nanostructure 30 including an n-type semiconductor material may be formed by etching the n-type semiconductor material 22.

According to an example embodiment, each of the semiconductor wafer 20 and the nanostructure 30 may include a group II nitride semiconductor material including a group III element and nitrogen (N). For example, each of the semiconductor wafer 20 and the nanostructure 30 may include at least one of AlN, GaN, InN, BN. AIBN, AlInN, AlGaN, InGaN, GaBN, AlGaBN, AlInBN, AlGaInBN, AlBInGaN, and AlGaInN, and may include, desirably, GaN. The nitrogen semiconductor may not be doped or may be doped with an n-type.

According to an example embodiment, the nanostructure 30 may have a height of 10 nm to 50 μm, desirably, a height of 100 nm to 5. Further desirably, the nanostructure 30 may have a height of 1 μm to 50 μm. When the height of the nanostructure 30 is included in the range, an electric field may be well formed at a nanostructure end and the electron emission efficiency may be enhanced.

According to an example embodiment, the nanostructure 30 is configured to emit an electron by applied voltage, and is a three dimensional (3D) structure of which an end portion is in a pointed shape to provide a high performance electron emission characteristic. The nanostructures 30 may be randomly or regularly arranged.

According to an example embodiment, the nanostructure 30 may be in a shape of at least one of a needle, a cone, and a polygonal pyramid. Desirably, the nanostructure 30 and may be in a needle shape. FIGS. 1D through 1G illustrate examples of a shape and an arrangement of a nanostructure according to an example embodiment. Referring to FIGS. 1D through 1F, the nanostructure 30 may be in a shape of, for example, a needle of FIG. 1D, a hexagonal pyramid of FIG. 1E, and a quadrangular pyramid of 1F.

According to an example embodiment, the nanostructure 30 may have an aspect ratio of 2 to 500, desirably, 5 to 500. Referring to FIG. 1G, the aspect ratio refers to a ratio of a longitudinal length b to a length a of a long shaft of a base in a cross-section of the nanostructure. When the aspect ratio is included in the range, an electric field may be well formed at a nanostructure end and the electron emission efficiency may be enhanced.

According to an example embodiment, the nanostructure 30 may be separate at an interval of 0.01 to 1 fold, desirably, 0.05 to 1 fold, of the height of the nanostructure 30. Referring to FIG. 1G, the interval c, c′ refers to an interval between a base of one nanostructure 30 and a base of the nanostructure 30 adjacent thereto. The arrangement of the nanostructures 30 may be adjusted based on the same interval or various intervals. For example, the interval c and the interval c′ may be the same as each other or differ from each other.

Example embodiments relate to a method of manufacturing an electron emitter.

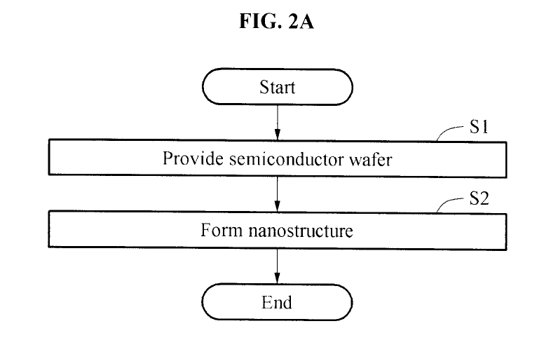

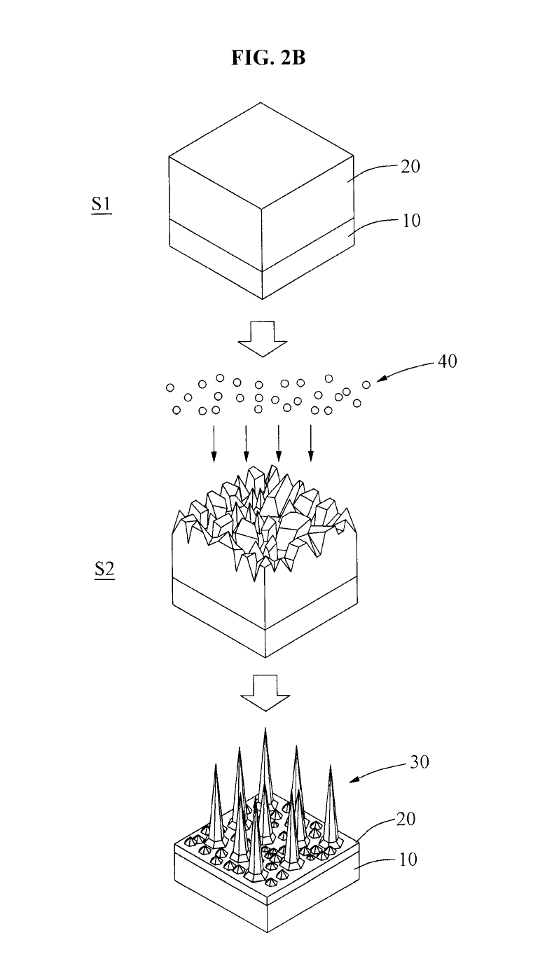

Hereinafter, a method of manufacturing an electron emitter according to an example embodiment will be described with reference to FIG. 2. FIG. 2A is a flowchart illustrating an example of a method of manufacturing an electron emitter according to an example embodiment. Referring to FIG. 2A, the electron emitter manufacturing method may include operation S1 of providing a semiconductor wafer and operation S2 of forming a nanostructure.

FIG. 2B illustrates an example of a process of manufacturing an electron emitter according to an example embodiment using cross-sectional views. Referring to FIG. 2B, operation S1 of providing a semiconductor wafer may be an operation of forming the semiconductor wafer 20 on a substrate. As described above, the semiconductor wafer 20 may include a group III nitride semiconductor material including a group III element and nitrogen (N).

Operation S2 of forming a nanostructure may be an operation of forming the nanostructure 30 on at least a portion of one surface of the semiconductor wafer 20 by etching the semiconductor wafer 20.

According to an example embodiment, the etching may use chemical etching to manufacture a nanostructure having the stability in terms of a shape and a large area. The chemical etching may use liquid, vapor, or both of the liquid and the vapor, and may be wet etching, dry etching, or electric etching. Desirably, the etching may be vapor dry etching.

According to an example embodiment, the chemical etching may select an etching temperature based on a type of etching and may be performed at the etching temperature of, desirably, 600° C. to 1200° C. A chemical etching material 40 may be appropriately selected based on the type of etching, and may use, desirably, HCl, NH₃, or etching gas including both of HCl and NH₃. The etching gas may be used with carrier gas, such as N₂.

According to an example embodiment, the etching gas may be supplied at the speed of over 0 sccm and 4000 sccm or less. Desirably, an appropriate supply speed may be selected based on a type of etching gas. For example, in the etching gas, HCl may be supplied at the speed of 100 sccm to 4000 sccm, desirably, at the speed of 500 sccm to 2000 sccm, and NH₃ may be supplied at the speed of over 0 sccm and 2000 sccm or less, desirably, at the speed of over 0 sccm and 1000 sccm or less.

The example embodiments relate to a light emitting device including an electron emitter.

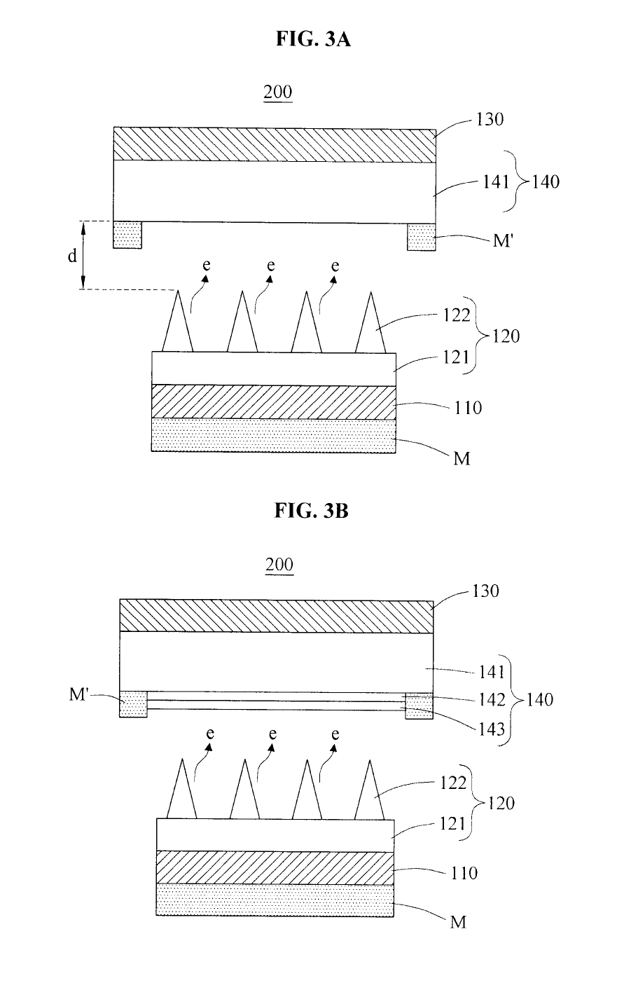

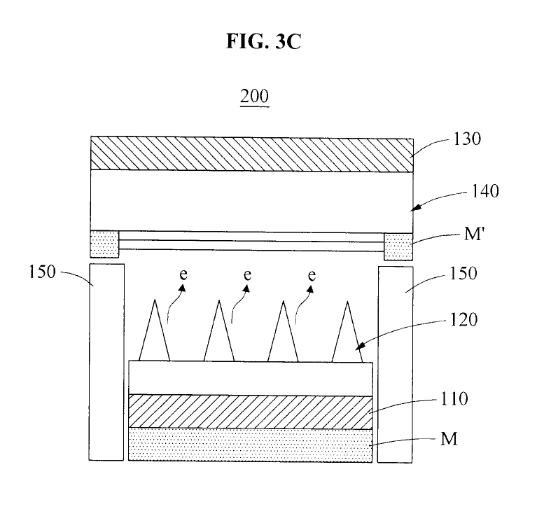

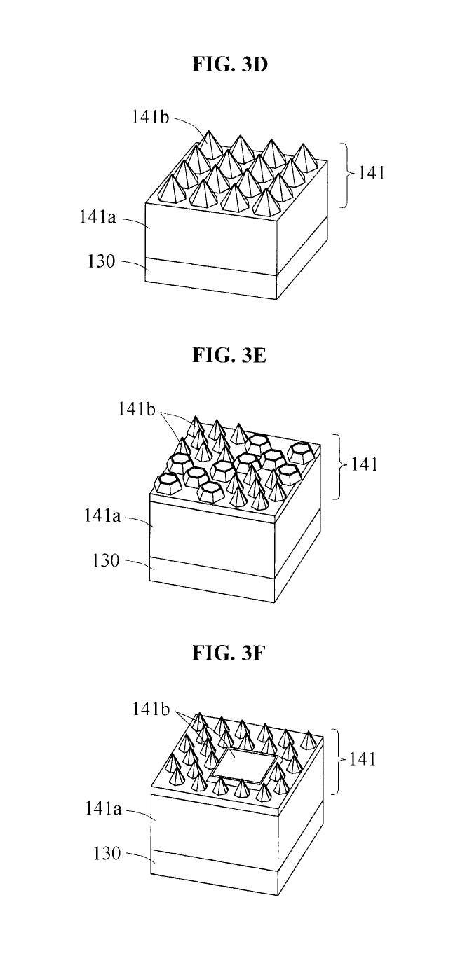

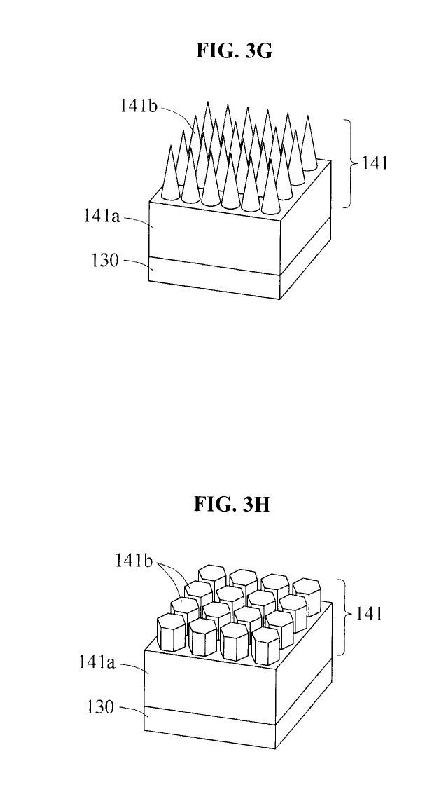

Hereinafter, a light emitting device according to an example embodiment will be described with reference to FIG. 3. FIG. 3A illustrates an example of a light emitting device 200 according to an example embodiment. Referring to FIG. 3A, the light emitting device 200 may include a first substrate 110, an electron emitting portion 120, a second substrate 130, a light emitter 140, a metal plate M, and a ground metal plate M′.

The first substrate 110 and the second substrate 130 may be provided to face each other and may be formed using the same component or different components. According to an example embodiment, each of the first substrate 110 and the second substrate 130 may be an amorphous or crystalline substrate that includes at least one of inorganic, organic, and metal materials. For example, each of the first substrate 110 and the second substrate 130 may include at least one of sapphire, diamond, LiAlO₂, Al, SiO₂, Si, SiC, GaN, Cu, Fe, Pt, and Pb. Each of the first substrate 110 and the second substrate 130 may have a thickness of 10 μm to 500 μm, desirably, a thickness of 50 μm to 200 μm.

According to an example embodiment, the electron emitting portion 120 may include a semiconductor wafer 121 provided on one surface of the first substrate and at least one nanostructure 122 formed on at least a portion of one surface of the semiconductor wafer 121. The aforementioned description may be applicable to the semiconductor wafer 121 and the nanostructure 122. An electron e emitted from the nanostructure 122 may be transferred to the light emitter 140 and may emit light using an electron injection scheme.

According to an example embodiment, the light emitter 140 may include a light emitting material layer 141 provided on surface of the second substrate 130 and provided toward nanostructure 122. The light emitting material layer 141 may include a single layer or a plurality of layers.

According to an example embodiment, the light emitting material layer 141 may include a light emitting material configured to emit light by the electrons e emitted from the electron emitting portion 120, and may include a group III nitride semiconductor material including a group III element and nitrogen (N). For example, the light emitting material layer 141 may include at least one of AlN, GaN. InN, BN. AIBN. AlInN, AlGaN. InGaN. GaBN, AlGaBN, AlInBN, AlGaInBN AlBInGaN, and AlGaInN, and may include, desirably, GaN. The nitrogen semiconductor may be doped or may not be doped. The light emitting material layer 141 may have a thickness of 1 nm to 20 μm, desirably, a thickness of 10 nm to 3 μm.

According to an example embodiment, the light emitting material layer 141 may include at least one structure, for example, two-dimensional (2D) structure or 3D structure, on at least a portion of the light emitting material layer 141. The structure may be in the same shape as that of the nanostructure 122 of the electron emitting portion 120 or may be in a shape of at least one of a film; a needle; a cone; a polygonal pyramid; a cylinder; a polygonal pillar; and a cone and a polygonal pyramid truncated to have a flat upper portion. A light emission wavelength may be adjusted based on the shape and the arrangement of the structure. For example, FIGS. 3D through 3H illustrate examples of a light emitting material layer according to an example embodiment. Referring to FIGS. 3D through 3H, the light emitting material layer 141 may include a lower end portion 141a of the light emitting material layer 141 formed on the substrate 130 and a structure 141b formed on the lower end portion 141a toward the electron emitting portion 120. The structure 141b may be provided in a shape of, for example, a hexagonal pyramid of FIG. 3D, a combination of a hexagonal pyramid and a hexagonal pyramid truncated to have a flat upper portion of FIG. 3E, a combination of a hexagonal pyramid and a square pillar truncated to have a flat upper portion of FIG. 3F, a needle of FIG. 3G, or a polygonal pillar of FIG. 3H. The structures 141b may have the same size or different sizes. For example, the structure 141b may have a base diameter of 10 nm to 30 μm and/or a height of 10 nm to 50 μm. The lower end portion 141a and the structure 141b may include the aforementioned light emitting material, and may be formed using the same component or different components. The structure 141b may be formed to be in contact with the lower end portion 141a or may be formed on the lower end portion 141a by forming a base layer on the substrate 130 and by etching the base layer.

According to an example embodiment, the light emitter 140 may be provided to have a gap d relative to the electron emitting portion 120. The gap d denotes a distance between the nanostructure 122 and the light emitting material layer 141, and a length of the gap d is adjustable. For example, the length of the gap d may be 0.1 mm to 5 mm, desirably, 0.1 mm to 2 mm. If the gap d is less than 0.1 mm, the nanostructure 122 of the electron emitting portion 120 may be in contact with the light emitter 140, which makes the electron emission difficult. If the gap d exceeds 2 mm, the emitted electron e may not reach the light emitter 140 and may reach an undesirable location.

According to an example embodiment, the metal plate M configured to connect to an external electrode may be provided on at least a portion of the first substrate 110. The external electrode may be a cathode. Also, the metal plate M′ connected to the external electrode may be provided on the second substrate 130, the light emitting material layer 141, or both of second substrate 130 and the light emitting material layer 141, desirably, at least a portion of one surface of the light emitting material layer 141. The external electrode may be ground and the metal plate M′ may be the ground metal plate M′. The metal plate M. M′ may include at least one of Ni, Al, Cu, Fe, Ag, Zn. Sn, Pb, Sb, Ti, In, V, Cr. Co, C, Ca, Mo, Au, P, W, Rh, Mn, B, Si, Ge. Se. Ln, Ga, Ir, and alloy thereof, and may include, desirably, Cu. The metal plate M, M′ may have a thickness of 0.1 mm to 5 mm. The metal plate M. M′ may be provided in various shapes, for example, a donut shape and a planar shape.

According to an example embodiment, a reflective layer 142, an electron collecting layer, or both of the reflective layer and the electron collecting layer 143 may be further sequentially provided toward the nanostructure 122 on at least a portion of one surface of the light emitting material layer 141. Referring to FIG. 3B, the reflective layer 142 may be formed on the light emitting material layer 141 and the electron collecting layer 143 may be formed on the reflective layer 142, toward the nanostructure 122.

According to an example embodiment, the reflective layer 142 may enhance the light extraction efficiency by preventing the loss of light emitted from the light emitting material layer 141. The reflective layer 142 may include a material capable of reflecting the light emitted from light emitting material layer 141, and may include, for example, at least one of Ni, Al, Cu, Fe, Ag, Zn, Sn, Pb, Sb, Ti, In, V, Cr, Co, C, Ca, Mo, Au, P. W, Rh, Mn, B, Si, Ge, Se, Ln, Ga, Ir, and alloy thereof. The reflecting layer 142 may include, desirably, Al, Ag. Au, and Cu, and, further desirably. Al. The reflective layer 142 may have a thickness of 10 nm to 200 nm.

According to an example embodiment, the electron collecting layer 143 may prevent the loss of electrons by collecting secondary electrons e emitted from the electron emitting portion 120 and by transferring the same to the light emitting material layer 141. The electron collecting layer 143 may include a material capable of collecting electrons and transferring the electrons to the light emitting material layer 141, and may include, for example, at least one of Ni, Al, Cu, Fe, Ag, Zn. Sn, Pb. Sb. Ti, In, V. Cr, Co. C, Ca, Mo, Au, P, W, Rh, Mn, B, Si, Ge, Se, Ln, Ga, Ir, and alloy thereof. The electron collecting layer 143 may include, desirably, Al, Ag, Au, and Cu. and, further desirably, Al. The electron collecting layer 143 may have a thickness of 10 nm to 200 nm.

According to an example embodiment, the light emitting device 200 may further include a length adjuster 150. Referring to FIG. 3C, the length adjuster 150 is configured to adjust a length of the gap d between the light emitter 140 and the electron emitting portion 120. Any type of devices capable of adjusting the length may be used for the length adjuster 150. Desirably, a length-adjustable Teflon screw may be used for the length adjuster 150.

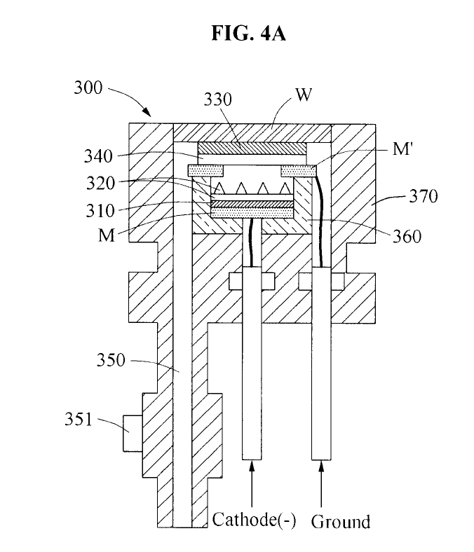

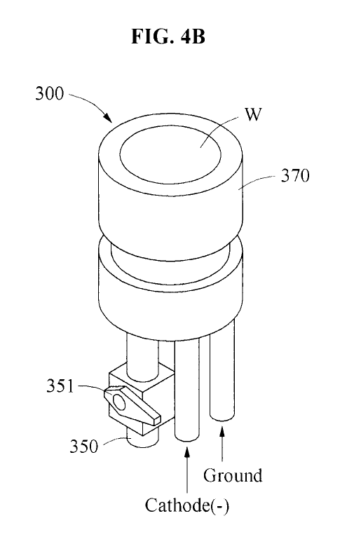

According to an example embodiment, there may be provided a light emitting device to which a vacuum device is connected. FIGS. 4A and 4B illustrate examples of a light emitting device 300 connected with a vacuum line according to an example embodiment. Referring to FIGS. 4A and 4B, the light emitting device 300 may include a first substrate 310, a second substrate 330, an electron emitting portion 320, a light emitter 340, a vacuum line 350, a length adjuster 360, a case 370, a metal plate M, a ground metal plate M′, and a window W, and may further include a reflective layer and an electron collecting layer (not shown).

The aforementioned description may be applicable to the first substrate 310, the second substrate 330, the electron emitting portion 320, the light emitter 340, the length adjuster 360, the metal plate M, and the ground metal plate M′.

According to an example embodiment, since the vacuum line 350 may be connected to an external vacuum device and may apply a vacuum state to or may remove the vacuum state from the light emitting device 300, it is possible to easily replace a part inside the light emitting device 300.

Any device applicable to the light emitting device 300 may be used for the case 370. For example, the case 370 may be a metal case capable of performing packaging using a vacuum chamber. A size of the metal case, for example, a length and a diameter of the metal case may be appropriately selected based on a size of an electron emitter, an applicable field of the light emitting device 300, and the like, and may be selected based on, for example, the applicable field, such as a small bulb, a micro bulb, a large bulb, and the like, of the light emitting device 300.

According to an example embodiment, the window W is provided in an upper portion of the case 370 through which ultraviolet (UV) rays generated from the light emitter 340 are emitted, and is formed using a transparent material so that the light emitted from a light emitting material layer included in the light emitter 340 is transferred to an outside. For example, the window W may be a transparent sheet, a plate, a film, etc., formed using, for example, quartz, transparent polymer, lead glass, and the like.

The light emitting device 300 may further include a configuration known in the art without departing from the scope of the example embodiment and further description related thereto is omitted here.

Although the example embodiments are described, various changes and modifications may be made without departing from the spirit and scope of the example embodiments disclosed in the following claims.

### Embodiment

Manufacturing of an Electron Emitter of a GaN Nanostructure

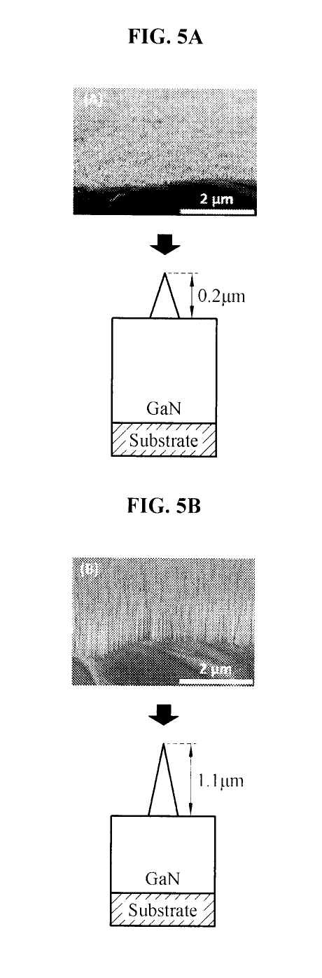

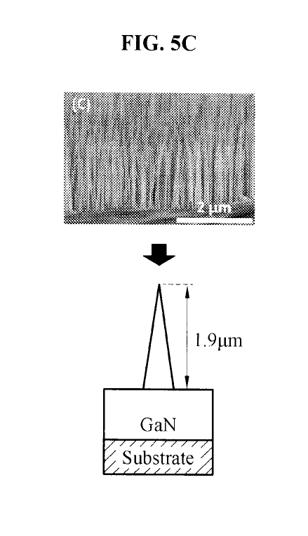

An electron emitter was manufactured by forming a GaN film with a diameter of 2 inches on a sapphire substrate, by placing the same in a furnace, and by performing etching using HCl and NH₃ chemical gas based on the conditions proposed in Table 1. Images of the manufactured electron emitter are shown in FIGS. 5A to 5C.

TABLE 1

| | Etching | Etching | HCl flow | | |
|---|---|---|---|---|---|
| | time | temperature | speed | NH₃ flow | Height |
| Embodiment | (min) | (° C.) | (sccm) | speed (sccm) | (μm) |
| (A) | 10 | 800 | 1000 | 200 | 0.2 |
| (B) | 10 | 900 | 1000 | 100 | 1.1 |
| (C) | 10 | 900 | 2000 | 0 | 1.9 |

Referring to FIGS. 5A to 5C, it can be verified that nanostructures may be uniformly formed on the large GaN film with 2 inches by applying a chemical vapor etching method according to example embodiments, and that a shape of a nanostructure may be adjusted based on a flow of etching gas and an etching temperature. If the HCl flow speed and the NH₃ flow speed are 1000 sccm and 100 sccm, respectively, it can be verified that it is possible to form a structure in a nano-needle shape having a vertical great aspect ratio and a pointed end.

Experiment 1

Electron Emission Characteristic of an Electron Emitter of a GaN Nanostructure

Electrons emitted from a GaN nano-needle electron emitter were measured by applying a cathode to a GaN nano-needle structure within a high vacuum chamber of about 10⁻⁶ torr and by grounding a cupper plate on a substrate provided on an opposite side. A result thereof is shown in Table 2 and FIG. 6.

TABLE 2

| | | Threshold |
|---|---|---|
| Embodiment | Turn-ON field @ 10 μA/cm² | field @1 mA/cm² |
| (A) | 3.9 | — |
| (B) | 3.3 | 5.6 |
| (C) | 2.7 | 4.5 |

Referring to Table 2 and FIG. 6, it can be verified that the shape with the relatively great aspect ratio and pointed end shows the relatively excellent electron emission characteristic.

Experiment 2

UV Emission Characteristic Using a GaN Film and an Electron Emitter of a GaN Nanostructure of Embodiment (C)

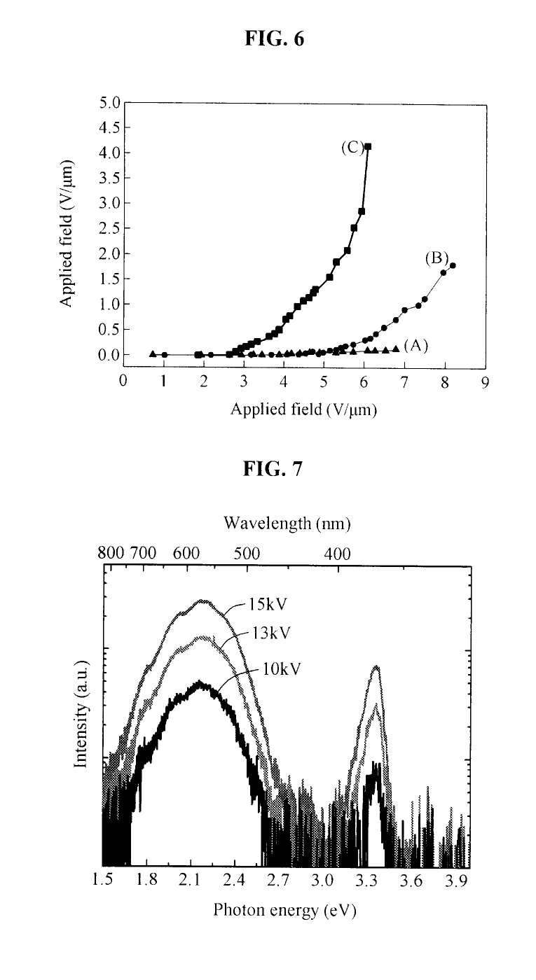

A light emission spectrum was measured by providing the GaN film on the opposite side of the GaN nano-needle electron emitter of embodiment (C) and by exciting the GaN film with emitted electrons according to a change in voltage in a GaN nano-needle. A result thereof is shown in FIG. 7.

Referring to FIG. 7, the GaN band edge emission wavelength (˜368 nm) and the wavelength (˜550 nm) associated with GaN defect can be verified. Also, it can be verified that the intensity of emitted spectrum varies based on the voltage applied to the GaN nano-needle electron emitter.

### Manufacture Example 1

Manufacturing an all-GaN Based UV Light Emitting Device Using a GaN Nano-Needle Electron Emitter and a GaN Light Emitting Material

An All-GaN based UV light emitting device was manufactured using a GaN nano-needle electron emitter and a GaN film according to example embodiment (C).

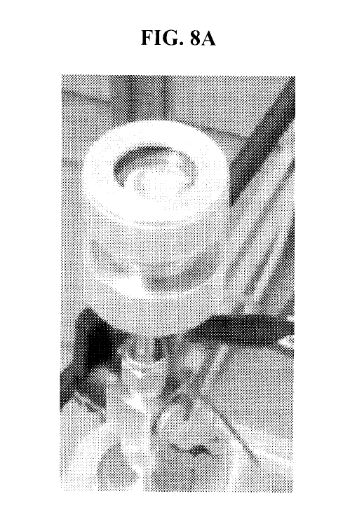

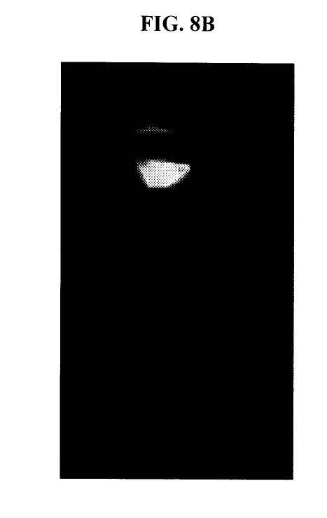

A cathode was applied by attaching a substrate of the GaN nano-needle electron emitter on a cupper plate and by attaching the donut-shaped copper plate on the GaN film provided on an opposite side. Here, a diameter of the cupper plate was about 1 cm, and an interval between the GaN nano-needle electron emitter and the GaN film was about 1 mm using a screw type Teflon. Packaging was overall performed using a vacuum chamber with the diameter of about 4.5 cm and the length of about 15 cm using a stainless metal. The vacuum chamber includes a vacuum valve capable of applying and maintaining a vacuum state. Herein, an electrode is drawn out of the vacuum chamber to apply the cathode and ground at an outside. A quartz glass plate with the diameter of about 3 cm was provided in an upper portion of the device and the device was manufactured so that UV rays generated from the device may be emitted through the quartz glass plate. A light emission phenomenon was observed by applying voltage of 3 to 10 kV to the manufactured device and a result thereof is shown in FIGS. 8A and 8B. Referring to FIGS. 8A and 8B, it can be verified that the UV light emitting device emits light (see FIG. 8B) according to an electron injection scheme (see FIG. 8A) using the GaN nano-needle electron emitter and without using a p-type (Al)GaN layer.

According to example embodiments, it is possible to manufacture a large-area GaN nanostructure having an excellent electron emission characteristic and excellent structural stability using chemical gas etching. Also, it is possible to provide an All-GaN based UV light emitting device using a GaN film by applying the GaN nanostructure as an electron emitter and by employing an electron injection scheme.

1. An electron emitter comprising:
a semiconductor wafer including a nanostructure formed on at least a portion of the semiconductor wafer.

2. The electron emitter of claim 1, wherein the nanostructure is formed using the same component as that of the semiconductor wafer and in a structure that continues from the semiconductor wafer.

3. The electron emitter of claim 1, wherein the nanostructure is formed on the semiconductor wafer through chemical etching and the nanostructure and the semiconductor wafer are in a continuous structure.

4. The electron emitter of claim 1, wherein the nanostructure is in a shape of at least one of a needle, a cone, and a polygonal pyramid.

5. The electron emitter of claim 1, wherein the nanostructure has an aspect ratio of 2 to 500.

6. The electron emitter of claim 1, wherein the nanostructure is separate at an interval of 0.01 to 1 fold of a height of the nanostructure.

7. The electron emitter of claim 1, wherein the nanostructure has a height of 10 nm to 50 μm.

8. The electron emitter of claim 1, wherein each of the semiconductor wafer and the nanostructure includes a group III nitride semiconductor including a group III element and nitrogen (N).

9. The electron emitter of claim 8, wherein the group III nitride semiconductor includes GaN.

10. A method of manufacturing an electron emitter of claim 1, the method comprising:
providing a semiconductor wafer; and
forming a nanostructure on at least a portion of the semiconductor wafer.

11. The method of claim 10, wherein the forming of the nanostructure comprises forming the nanostructure through at least one of chemical etching, wet etching, dry etching, and electric etching, and
the chemical etching is performed using HCl, NH₃, or both of HCl and NH₃.

12. A light emitting device comprising:
a first substrate and a second substrate provided to face each other;
an electron emitting portion including a semiconductor wafer layer provided on one surface of the first substrate and including a nanostructure formed on at least a portion of the semiconductor wafer layer; and
a light emitter including a light emitting material layer provided on one surface of the second substrate and provided toward the nanostructure.

13. The light emitting device of claim 12, wherein the light emitting material layer includes a light emitting material that emits light by an electron emitted from the electron emitting portion, and
the light emitting material layer has a thickness of 1 nm to 20 μm.

14. The light emitting device of claim 12, wherein the electron emitting portion and the light emitter are provided so that a gap is formed between the electron emitting portion and the light emitter, and a length of the gap is adjustable.

15. The light emitting device of claim 12, wherein the first substrate and the second substrate are formed using the same component or different components, and each of the first substrate and the second substrate includes at least one of sapphire, diamond sapphire, diamond, LiAlO₂, Al, SiO₂, Si, SiC, GaN, Cu, Fe, Pt, and Pb, and has a thickness of 10 μm to 500 μm.

16. The light emitting device of claim 12, wherein a reflective layer, an electron collecting layer, or both of the reflective layer and the electron collecting layer are further sequentially provided toward nanostructure on at least a portion of one surface of the light emitting material layer.

17. The light emitting device of claim 16, wherein each of the reflective layer and the electron collecting layer includes at least one of Ni, Al, Cu, Fe, Ag, Zn, Sn, Pb, Sb, Ti, In, V, Cr, Co, C, Ca, Mo, Au, P, W, Rh, Mn, B, Si, Ge, Se, Ln, Ga, Ir, and alloy thereof, and
each of the reflective layer and the electron collecting layer has a thickness of 10 nm to 200 nm.

18. The light emitting device of claim 12, wherein a metal plate configured to connect to an external electrode is provided on at least a portion of the first substrate and the light emitting material layer.
